(19) United States
(12) Patent Application Publication
(10) Pub. No.: US 2024/0247683 A1
(43) Pub. Date: Jul. 25, 2024

(54) HINGE DEVICE OF FOLDABLE MOBILE DEVICE USING FLEXIBLE DISPLAY PANEL

(71) Applicant: EMB CO.,LTD., Anyang-si, Gyeonggi-do (KR)

(72) Inventors: Sung Chun HONG, Seoul (KR); Hyun Taek JUNG, Seoul (KR); Chang Soo KIM, Incheon (KR)

(21) Appl. No.: 18/293,791

(22) PCT Filed: Aug. 24, 2022
(86) PCT No.: PCT/KR2022/012630

§ 371 Date: Jan. 31, 2024

(30) Foreign Application Priority Data
Aug. 24, 2021 (KR) 10-2021-0111963

(51) Int. Cl. F16C 11/04; H05K 5/02

(52) U.S. Cl. CPC F16C 11/04; H05K 5/0226

(57) ABSTRACT

A hinge device of the present invention comprises: a housing positioned between an end of a first body and an end of a second body, which interwork and move relative to each other; first and second hinge blades fixed to the first and second bodies, respectively, and rotatably supported by the housing, respectively, so as to make rotating movements by a predetermined angle between “an unfolded position” in which the first and second bodies are on the same horizontal line and “a folded position” in which the first and second bodies face and fold onto each other; and first and second sloping plates installed on the first and second hinge blades, respectively, and configured to interwork by pressurization during rotational movements of the first and second hinge blades so as to move between a horizontal position in which same are aligned with horizontal lines of the first and second bodies in the “unfolded position” and a sloping position in which same are disposed to slope from the horizontal lines of the first and second bodies, respectively, such that a folding space is formed between the first and second hinge blades in the “folded position”. According to the present invention, a predetermined radius of curvature is formed on a folding portion of the flexible display panel when the first and second bodies are folded, and the outside and inside shapes of the first and second bodies can be parallel to each other.

### TECHNICAL FIELD

The present invention relates to a hinge device of a foldable mobile device using a flexible display panel, and more specifically, to a hinge device which can maintain the horizontal level of the flexible display panel when a first body and a second body that can be folded are at an unfolded position, form a predetermined radius of curvature in a folding unit of the flexible display panel when the first body and the second body are at a folded position, and form outer and inner sides of the bodies to be parallel while the inner sides are in contact with each other.

### BACKGROUND ART

Recently, with the advancement in the fields of semiconductor, software, and communications, various functions for improving convenience have been added or improved and applied to mobile devices such as tablet PCs, smartphones and the like.

For example, foldable mobile devices, which can be formed to be partitioned into a first body 1 and a second body 2 and reduce the size by folding the first body 1 and the second body 2 as shown in FIGS. 1a and 1b, has been improved by applying a flexible display panel 3 so that the screen of the flexible display panel 3 can be viewed larger at an unfolded position as shown in FIG. 1a.

In order to apply the flexible display panel 3 to such a foldable mobile device, it is very important to form a predetermined radius of curvature R in the folding unit P of the flexible display panel 3 at a folded position of the first body 1 and the second body 2 as shown in FIG. 1b. When the predetermined radius of curvature R is not formed in the folding unit P, the flexible display panel 3 may be damaged due to a bending phenomenon, or the lifespan of the mobile device is shortened as the folding unit P is deteriorated due to repeated folding operations.

Accordingly, in the prior art, a hinge device that forms a predetermined radius of curvature R in the folding unit P of the flexible display panel 3 at a position of folding the first body 1 and the second body 2 has been proposed and disclosed in in Korean Patent Publication No. 10-2019-0124110, 10-2020-0011100, and the like.

However, in the prior art described above, the inner sides of the first body 1 and the second body 2 are formed in a tapered shape having a gap gradually increasing from an end portion to the folding unit P as shown in FIG. 1b in order to secure a folding space for accommodating a predetermined radius of curvature R formed in the folding unit P of the flexible display panel 3 at the folded position of the first body 1 and the second body 2.

In addition, since the thickness of the first body 1 and the second body 2 is uniform, the outer sides of the first body 1 and the second body 2 are in a tapered shape of which the thickness gradually increases from the end portions in contact with each other toward the folding unit P.

Accordingly, as the outer shape is in a tapered shape when the first and second bodies 1 and 2 are folded, in which the folding unit P side is thick and the end portion side is thin, the foldable mobile device using a flexible display panel of the prior art is not simple compared to those of which the outer shapes of the first and second bodies 1 and 2 are parallel, and has a disadvantage of contaminating the surface of the flexible display panel 3 as foreign substances flow in through the gap formed between the first and second bodies 1 and 2 when carried.

### DISCLOSURE OF INVENTION

### Technical Problem

Therefore, the present invention has been made in view of the above problems, and it is an object of the present invention to provide a hinge device of a foldable mobile device using a flexible display panel, which has a simple outer shape as a predetermined radius of curvature is formed in a folding unit of the flexible display panel while the first body and the second body are in a folded state and the shapes of the outer side and the inner side are in parallel as the inner sides of the first body and the second body are in contact with each other, and is capable of preventing contamination of the flexible display panel caused by inflow of foreign substances as there is no gap between the first body and the second body.

### Technical Solution

To accomplish the above object, according to one aspect of the present invention, there is provided a hinge device comprising: a housing positioned between one-end portions of a first body and a second body performing a relative motion with each other; a first hinge blade and a second hinge blade fixed to the first body and the second body and rotationally supported on the housing to perform rotation movement as much as a predetermined angle between an ‘unfolded position’ at which the first body and the second body are placed on the same horizontal line and a ‘folded position’ at which the first body and the second body are facing and in contact with each other; and a first sloping plate and a second sloping plate installed on the first hinge blade and the second hinge blade, respectively, to interwork by pressure during the rotation movement of the first hinge blade and the second hinge blade so as to move between a horizontal position aligned with a horizontal line of the first body and the second body at the ‘unfolded position’ and a sloping position arranged to be inclined from the horizontal line of the first body and the second body so that a folding space is formed between the first hinge blade and the second hinge blade at the ‘folded position’.

In addition, in the present invention, the first sloping plate and the second sloping plate interwork by a first pressing means, wherein the first pressing means is configured of first elastic members for providing an elastic force so that the first sloping plate and the second sloping plate are always at the sloping position, and first pressing protrusions for maintaining the first hinge blade and the second hinge blade at the horizontal position by pressing the first sloping plate and the second sloping plate when the first hinge blade and the second hinge blade rotate to the ‘unfolded position’.

In addition, in the present invention, as rotation support grooves are formed on the first hinge blade and the second hinge blade, and rotation support protrusions are formed on the first sloping plate and the second sloping plate, the first and second sloping plates may rotate as much as a predetermined angle between the horizontal position and the sloping position around the rotation support protrusions.

In addition, in the present invention, assembly holes of the first hinge blade and the second hinge blade combined with the first sloping plate and the second sloping plate are formed to be slightly long in a rotation direction of the first sloping plate and the second sloping plate to guide the first sloping plate and the second sloping plate to rotate as much as a predetermined angle.

In addition, in the present invention, as sloping surfaces that can be tightly attached to the first sloping plate and the second sloping plate at the sloping positions of the first sloping plate and the second sloping plate are formed on the first hinge blade and the second hinge blade, a folding space is formed always at a predetermined sloping position by a pressing member.

In addition, in the present invention, the hinge device further comprises a lifting plate installed in the housing to be positioned in a folding space between the first sloping plate and the second sloping plate, to interwork by pressure during the rotation movement of the first hinge blade and the second hinge blade, so as to move between an ascending position spaced apart from the housing to connect a gap between the first sloping plates and the second sloping plates on the same horizontal line at the unfolded position and a descending position close to the housing to form a folding space between the first hinge blade and the second hinge blade at the folded position.

In addition, in the present invention, the lifting plate interworks by a second pressing means, wherein the second pressing means is configured of second elastic members for providing an clastic force so that the lifting plate is always at the descending position, and second and third pressing protrusions for pressing the lifting plate to move to the ascending position and the descending position.

In addition, the hinge device according to the present invention allows the display panel attached to the first and second bodies to be folded in parallel, in portions other than the folding unit, while forming a predetermined radius of curvature in the folding unit.

### Advantageous Effects

According to the present invention having the characteristic configuration as described above, at the unfolded position of the bodies, the first and second sloping plates of the hinge device move to a horizontal position to maintain the folding unit of the flexible display panel in a horizontal state, and at the folded position of the bodies, the first and second sloping plates move to a sloping position to form a folding space that can accommodate a predetermined radius of curvature formed in the folding unit of the flexible display panel, and therefore, the radius of curvature may be formed in the folding unit, and the outer and inner sides of the bodies may be formed to be parallel while the inner sides of the bodies are in contact with each other. Therefore, there is an effect of simplifying the outer shape of the mobile device and preventing contamination of the flexible display panel caused by inflow of foreign substances by eliminating the gap between the bodies.

In addition, according to the present invention, at the folded position of the bodies, the lifting plate moves to a descending position to form a folding space that can accommodate a predetermined radius of curvature formed in the folding unit of the flexible display panel, and at the unfolded position of the bodies, the lifting plate of the hinge device moves to the ascending position to connect the gap between the first and second sloping plates at the horizontal position on the same horizontal line, and therefore, there is an effect of continuously and securely maintaining the horizontal state of the folding unit of the flexible display panel at the unfolded position.

### BRIEF DESCRIPTION OF THE DRAWINGS

FIGS. 1a and 1b are side views showing an unfolding position and a folding position of a conventional foldable mobile device.

FIGS. 2a and 2b are side views showing an unfolding position and a folding position of a foldable mobile device according to the present invention.

FIG. 3 is a perspective view showing a flexible display panel separated from first and second bodies at an unfolded position of a mobile device according to the present invention.

FIG. 4 is an exploded perspective view showing the connection relation between the first and second bodies and the hinge device in FIG. 3.

FIG. 5 is a perspective view separately showing major components of a hinge device according to the present invention.

FIG. 6 is an exploded perspective view of the first and second hinge blades and the housing showing the rotation-supporting structure of the first and second hinge blades in a hinge device of the present invention.

FIGS. 7a and 7b are cross-sectional views showing the rotation-supporting structure of the first and second hinge blades in FIG. 6.

FIG. 8 is an exploded perspective view showing the interworking structure of the first and second hinge blades and the slide member in a hinge device of the present invention.

FIG. 9 is an exploded perspective view showing the bottom portions of the housing and the slide member in FIG. 8.

FIGS. 10a and 10b are operation state views showing the interworking operation of the slide member and the hinge blade in a hinge device of the present invention.

FIG. 11 is a partially exploded perspective view showing the tension mechanism in a hinge device according to the present invention.

FIG. 12 is an exploded perspective view showing the connection configuration of the tension mechanism and the first and second hinge blades in a hinge device according to the present invention.

FIGS. 13a and 13b are views showing the operation state of the tension mechanism in a hinge device of the present invention.

FIGS. 14a and 14b are cross-sectional views taken along the line A-A in FIG. 4, showing the installation configuration of the first and second sloping plates and the operation state by the first elastic members of the first pressing means in a hinge device of the present invention.

FIGS. 15a and 15b are cross-sectional views showing the operation state of the first and second sloping plates by the first pressing protrusions of the first pressing means.

FIG. 16 is an exploded perspective view showing the installation state of the lifting plate and the tension mechanism in a hinge device of the present invention.

FIGS. 17a and 17b are cross-sectional views showing the installation configuration of the lifting plate and the operation state by the second elastic members of the second pressing means in FIG. 16.

FIGS. 18a and 18b are cross-sectional views showing the operation state of the lifting plate by the second and third pressing protrusions of the second pressing means in FIG. 16.

### DESCRIPTION OF SYMBOLS

### Description of Symbols

11, 12: First and second bodies
13: Flexible display panel
14: Hinge device
21, 22: First and second hinge blades
31: Housing
50: Tension mechanism
55, 56: First and second tension blades
61,62: First and second sloping plates
63a: First elastic member
63b: First pressing protrusion
63c: Sloping surface
70: Lifting plate
73, 74: Second and third pressing protrusions
75: Second elastic member
P: Folding unit
R: Radius of curvature

### BEST MODE FOR CARRYING OUT THE INVENTION

The detailed description of the present invention is described below with reference to the accompanying drawings, which shows, as an example, specific embodiments in which the present invention may be embodied. These embodiments are described in detail as sufficient as to embody the present invention by those skilled in the art. It should be understood that although the various embodiments of the present invention are different from one another, they are not necessarily mutually exclusive. For example, specific shapes, structures and characteristics described herein may be implemented in other embodiments without departing from the spirit and scope of the present invention in relation to an embodiment. In addition, it should be understood that the location or arrangement of individual components within each disclosed embodiment may be changed without departing from the spirit and scope of the present invention. Accordingly, the detailed description described below is not intended to be taken in a limiting sense, and the scope of the present invention, if properly described, includes all equivalents as claimed in the claims. In the drawings, similar reference numerals refer to identical or similar functions across several aspects.

Hereinafter, preferred embodiments of the present invention will be described in detail with reference to the accompanying drawings.

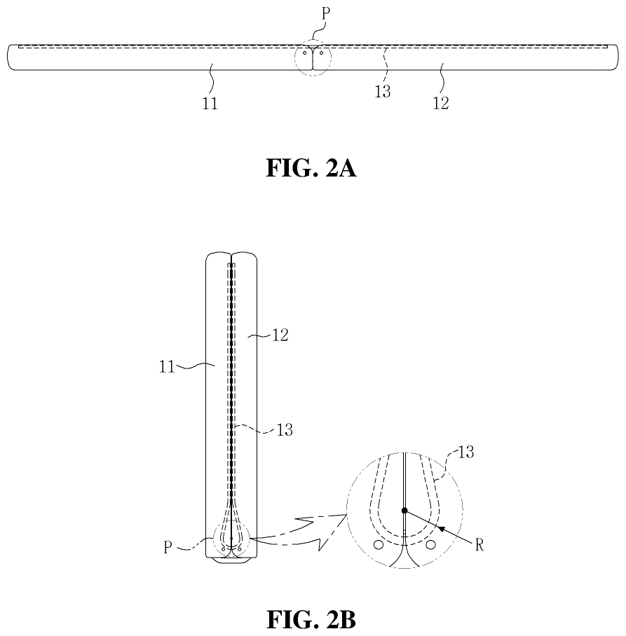

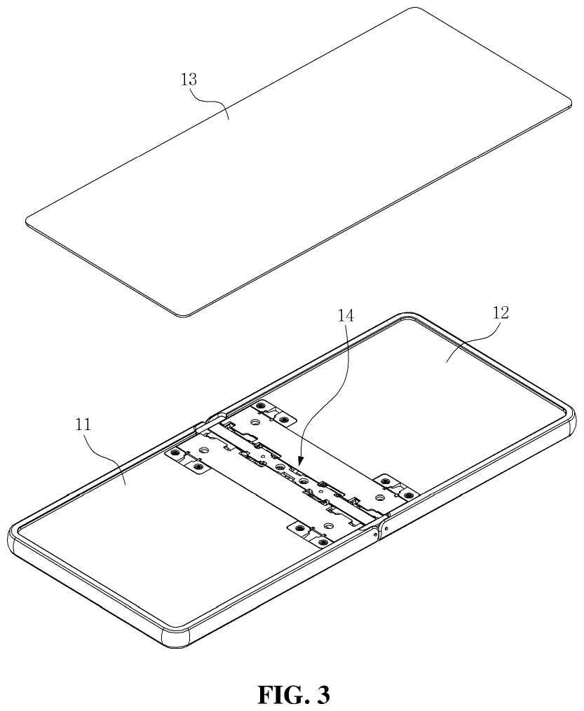

FIGS. 2a and 2b are side views showing an unfolding position and a folding position of a foldable mobile device according to the present invention. At the ‘unfolded position’ in which the first body 11 and the second body 12 formed separately are unfolded in the horizontal direction as shown in FIG. 2, it is possible to use a wide screen as the inner sides of the first body 11 and the second body 12 are positioned on the same horizontal line and the flexible display panel 13 installed on the inner sides of the first body 11 and the second body 12 also maintains a horizontal state.

In addition, as the flexible display panel 13 is folded in a parallelly folded shape (hereinafter, referred to as a ‘dumbbell shape’) at the ‘folded position’ where the inner sides of the first body 11 and the second body 12 are in contact with each other as shown in FIG. 2b, other than the folding unit, while forming a predetermined radius of curvature R in the folding unit P, and therefore, the inner sides of the first body 11 and the second body 12 are in contact with each other and the shapes of the outer side and the inner side are parallel at the ‘folded position’, the outer shape of the mobile device is simple, and there is provided a function of preventing contamination of the flexible display panel 13 caused by inflow of foreign substances by eliminating the gap between the first body 11 and the second body 12. The present invention may also be applied at a radius of curvature smaller than 1.5 R (a radius of curvature having a radius of 1.5 mm), which is the radius of curvature R of the folding unit of a foldable mobile device currently applying a flexible display panel. This function is performed by the hinge device of the present invention described below in detail.

FIG. 3 is a perspective view showing the flexible display panel 13 separated from the first and second bodies 11 and 12 at an unfolded position of a mobile device according to the present invention, and a hinge device 14 is installed to be connected between one-end portions where the folding units of the first body 11 and the second body 12 face each other.

The flexible display panel 13 is formed in a size that may cover the entire area of the first and second bodies 11 and 12 including the hinge device 14, and is fixed to the inner side of the bodies 11 and 12, excluding the hinge device 14, with an attachment means such as an adhesive or the like.

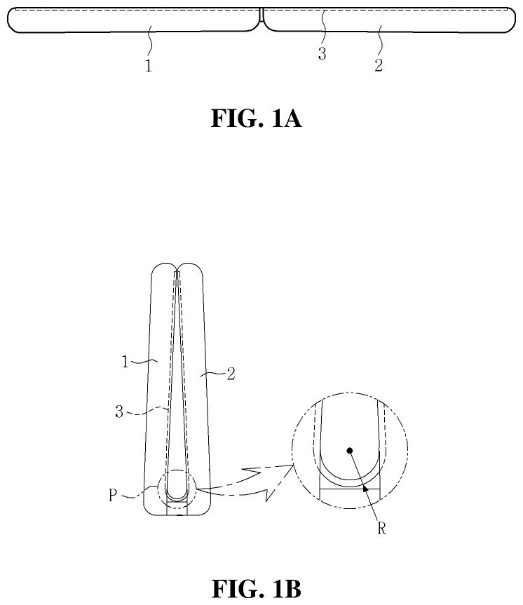

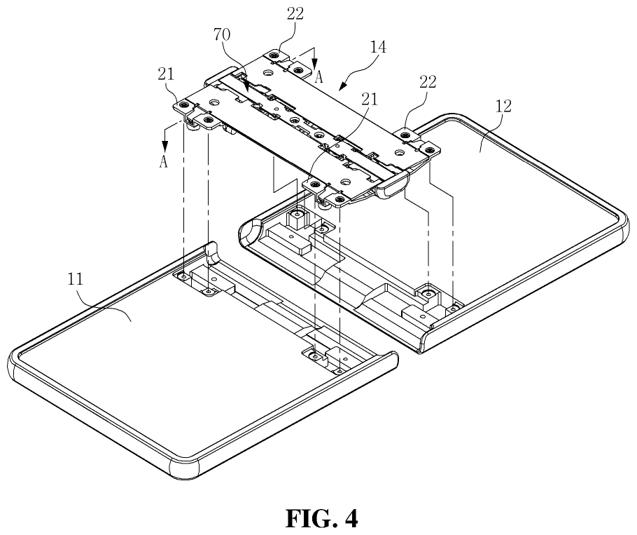

FIG. 4 is an exploded perspective view showing the connection relation between the first and second bodies 11 and 12 and the hinge device 14 in FIG. 1. The hinge device 14 has first and second hinge blades 21 and 22, and the hinge device 14 is coupled to the first and second bodies 11 and 12 by fixing the first and second hinge blades 21 and 22 to the first body 11 and the second body 12 using screws (not shown).

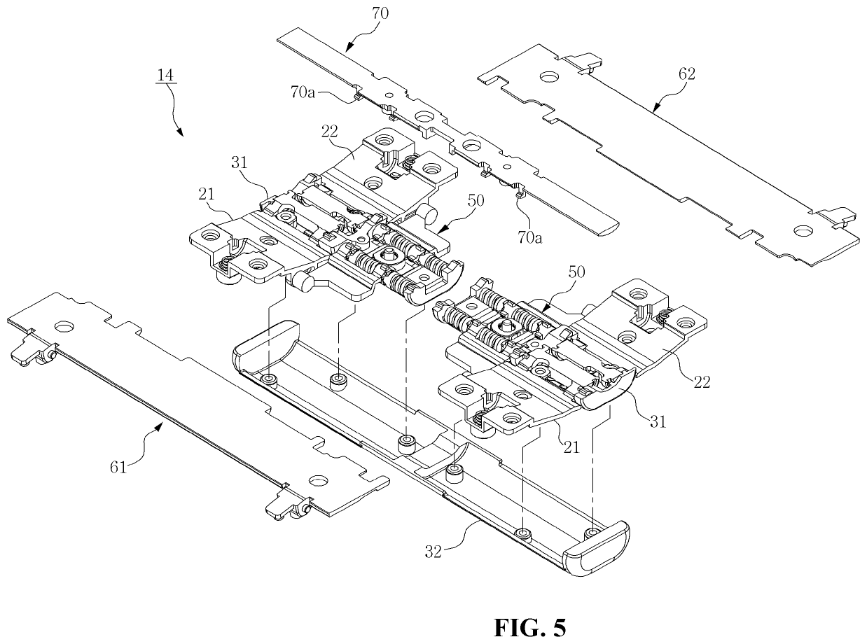

FIG. 5 is a perspective view showing disassembled major components of a hinge device 14. As shown in the figure, the hinge device 14 includes a housing 31 for supporting the first and second hinge blades 21 and 22 to rotate as much as a predetermined angle, i.e., between the ‘unfolded position’ and the ‘folded position’ of the first and second bodies 11 and 12, and a tension mechanism 50 for performing a free stop function between the ‘unfolded position’ and the ‘folded position’ during the rotation movement of the first and second hinge blades 21 and 22.

The first and second hinge blades 21 and 22, the housing 31, and the tension mechanism 50 are installed at both ends of the connection end portions of the first and second bodies 11 and 12 in the same configuration for the sake of stable folding of the first and second bodies 11 and 12, and the housings 31 and the tension mechanisms 50 on both sides are fixed to a hinge cover 32 using screws (not shown).

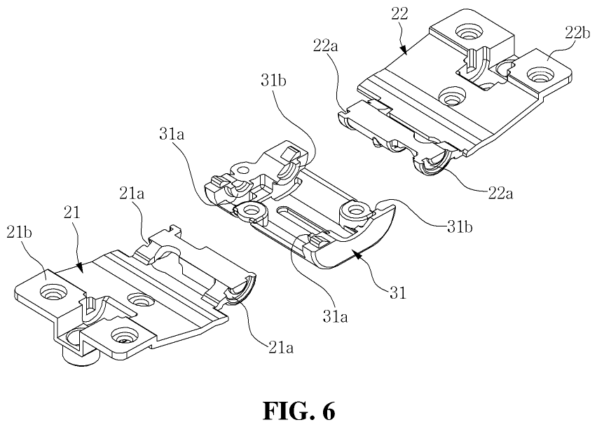

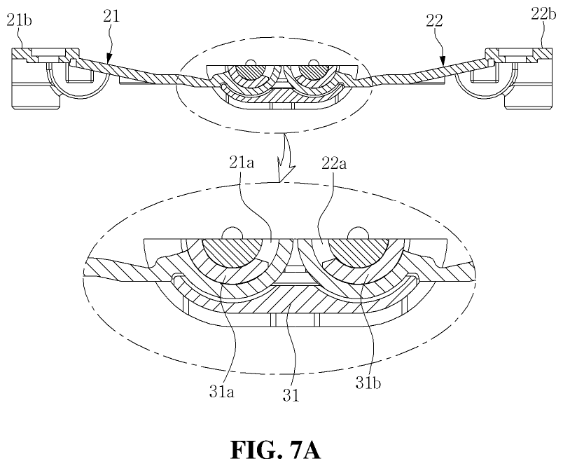

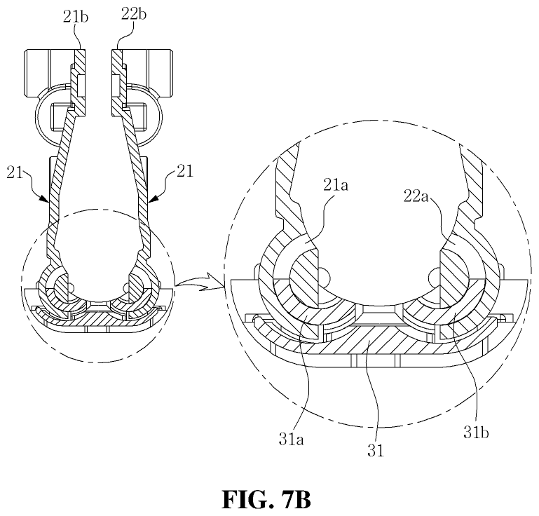

FIGS. 6, 7a and 7b show the rotation-supporting structure of the first and second hinge blades 21 and 22 in the hinge device 14 of the present invention. They are shown as major configurations to easily explain the rotation-supporting structure of the first and second hinge blades 21 and 22 shown in FIG. 6. As shown in the figure, the rotation-supporting structure of the first and second hinge blades 21 and 22 includes a pair of semicircular protrusions 31a and 31b formed on both inner walls of the housing 31 to be spaced a predetermined distance apart, and semicircular grooves 21a and 22a formed on the first and second hinge blades 21 and 22, into which the semicircular protrusions 31a and 31b are insert-fitted to be rotationally supported.

As the semicircular grooves 21a and 22a of the first and second hinge blades 21 and 22 are formed at the opposite ends of the fixing units 21b and 22b to which the first and second bodies 11 and 12 are fixed so that the fixing units 21b and 22b sides may rotate as much as a predetermined angle around the semicircular grooves 21a and 22a, the first and second bodies 11 and 12 may rotationally support between the ‘unfolded position’ and the ‘folded position’.

At this point, the distance between the semicircular protrusions 31a and 31b is set so that a folding space may be formed between the first and second hinge blades 21 and 22 to accommodate a predetermined radius of curvature R formed in the folding unit P of the flexible display panel 13 at the ‘folded position’.

Although it is described as an example in this embodiment that the semicircular grooves 21a and 22a are formed on the first and second hinge blades 21 and 22, and the semicircular protrusions 31a and 31b are formed on the housing 31, contrarily, the semicircular protrusions 31a and 31b may be formed on the first and second hinge blades 21 and 22, and semicircular grooves 21a and 22a may be formed on the housing 31.

Although an embodiment of the rotation-supporting structure of the hinge blades has been described above, any configuration that can rotationally support the bodies 11 and 12 may be applied to the present invention in combination with a configuration including the interworking means, the sloping plate, and the lifting plate described below.

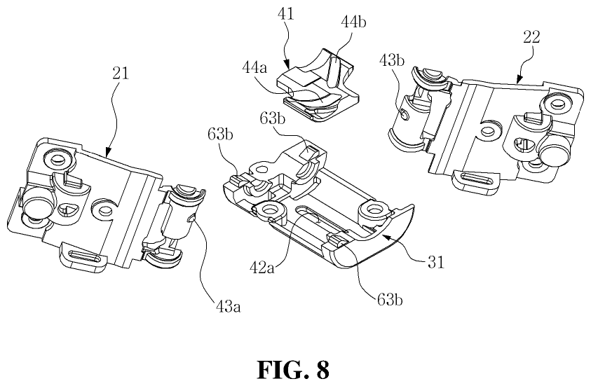

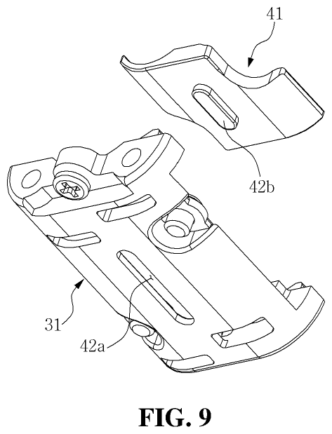

FIGS. 8 and 9 show the first and second hinge blades 21 and 22, the housing 31, and the interworking means, and a slide member 41 is provided in the housing 31 as an interworking means for performing a relative motion of the first hinge blade 21 and the second hinge blade 22 with each other.

The slide member 41 is installed in the housing 31 to reciprocate a predetermined distance in the direction of the rotation axis line of the first and second hinge blades 21 and 22 (hereinafter, referred to as ‘hinge axis line’).

The moving structure of the slide member 41 is accomplished by forming a rectangular slide hole 42a in the housing 31 in the direction of hinge axis line, and forming a slide protrusion 42b inserted and guided in the slide hole 42a on the bottom surface of the slide member 41.

In addition, the interworking means includes first and second slope guide protrusions 43a and 43b formed on the bottom surfaces of the first and second hinge blades 21 and 22, and first and second slope guide grooves 44a and 44b formed on the top surface of the slide member 41 in correspondence thereto. The portions where the first and second slope guide protrusions 43a and 43b are formed on the bottom surfaces of the first and second hinge blades 21 and 22 are formed in the shape of a curved surface in the rotation direction of the first and second bodies 11 and 12. In addition, it is preferable that the portions in the slide member 41, where the first and second slope guide grooves 44a and 44b are formed, are also formed in the shape of a curved surface along the length in correspondence to the portions where the first and second slope guide protrusions 43a and 43b are formed.

The first and second slope guide grooves 44a and 44b formed on the top surface of the slide member 41 are formed in the directions sloped and offset from each other with respect to the moving direction of the slide member 41. That is, the first slope guide groove 44a and the second slope guide groove 44b are formed to be sloped in the diagonal directions with respect to the moving direction of the slide member 41, and the sloped directions (diagonal directions) are formed in the directions offset from each other, rather than the same direction.

At this point, the sloped angles of the first slope guide groove 44a and the second slope guide groove 44b are preferably the same on the basis of the moving axis line of the slide member 41. Accordingly, as the rotational moving distances of the first slope guide protrusion 43a and the second slope guide protrusion 43b according to the linear movement of the slide member 41 are the same, when the first and second hinge blades 21 and 22 interwork to rotationally move between the ‘unfolded position’ and the ‘folded position’, they may rotationally move the same distance.

The first and second slope guide protrusions 43a and 43b moving while being engaged with the first and second slope guide grooves 44a and 44b are formed at corresponding positions on the bottom surfaces of the first and second hinge blades 21 and 22. The first and second slope guide protrusions 43a and 43b may be formed in a hemispherical or rectangular shape. The first and second slope guide protrusions 43a and 43b are preferably formed in a shape of which the width decreases toward the top, and therefore, vibration and noise can be reduced as friction is reduced when they are engaged with the first and second slope guide grooves 44a and 44b.

As the first and second slope guide protrusions 43a and 43b move diagonally along the curved surface in the directions offset from each other along the first and second slope guide grooves 44a and 44b in association with the linear movement of the slide member 41 in this way, the first and second hinge blades 21 and 22, on which the first and second slope guide protrusions 43a and 43b are formed, interwork with each other and rotate between the ‘unfolded position’ and the ‘folded position’.

In addition, in the interworking structure of the first and second hinge blades 21 and 22, although only any one of the first and second hinge blades 21 and 22 rotates to the ‘folded position’ or ‘unfolded position’, as the first and second slope guide protrusions 43a and 43b move while being engaged with the first and second slope guide grooves 44a and 44b, and the slide member 41 interworking with this moves linearly as much as a predetermined length in the direction of hinge axis line, the other side performs a relative motion in the opposite direction and rotates to the ‘folded position’ or ‘unfolded position’ at the same time.

Although an embodiment of the interworking means that performs a relative motion on the hinge blades has been described above, any configuration that performs a relative motion on the hinge blades or the bodies may be applied to the present invention in combination with the characteristic configuration including the sloping plate and lifting plate described below.

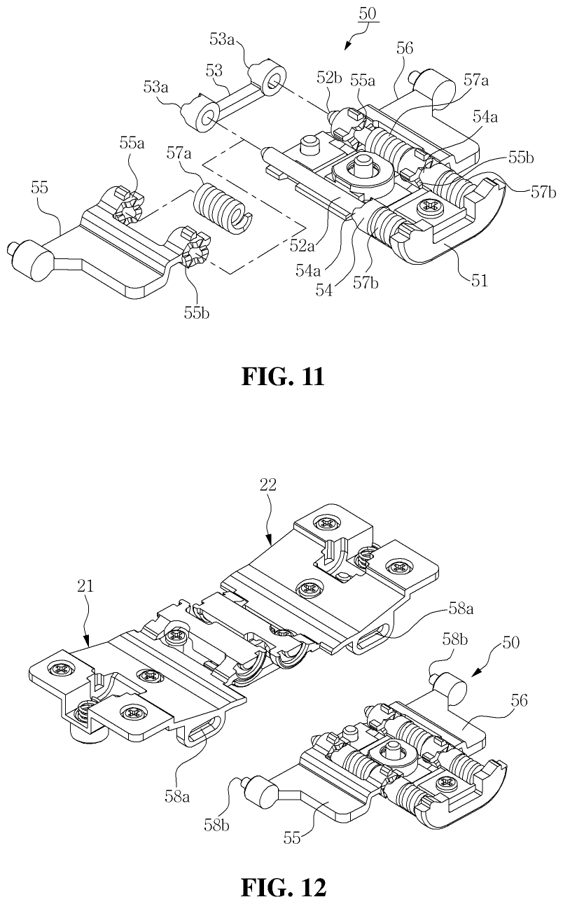

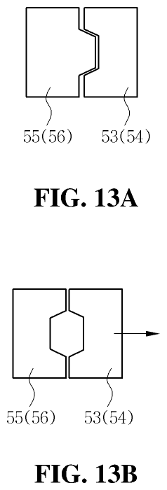

FIG. 11 is a perspective view of the tension mechanism 50 showing some components separated from the hinge device 14 of the present invention.

As shown in the figure, the tension mechanism 50 is provided with a tension fixed member 51 fixed to the hinge cover 32 (see FIG. 5), and first and second guide shafts 52a and 52b are provided in the tension fixed member 51 in the direction of hinge axis line. Tension operating members 53 and 54 are installed to be inserted into the first and second guide shafts 52a and 52b to be movable in the axis direction, and a plurality of slope protrusions 53a and 54a is formed in the tension operating members 53 and 54 in the circumferential direction around the first and second guide shafts 52a and 52b to protrude in the direction of hinge axis line.

In addition, the tension mechanism 50 includes first and second tension blades 55 and 56 installed to be inserted into the first and second guide shafts 52a and 52b to be rotationally supported and to be movable in the axis direction. Other slope protrusions 55a and 56a that can be insert-fitted between the slope protrusions 53a and 54a of the tension operating members 53 and 54 in correspondence thereto are formed in the first and second tension blades 55 and 56.

A first spring 57a is installed between the tension operating member 53 and the first and second tension blades 55 and 56, and a second spring 57b is elastically installed as an elastic member between the tension operating member 54 and the tension fixed member 51. The first and second springs 57a and 57b are installed to always provide elastic force in the direction of insert-fitting the slope protrusions 53a and 54a of the tension operating members 53 and 54 into the slope protrusions 55a and 56a of the first and second tension blades 55 and 56.

FIG. 12 is a view showing the connection configuration of the tension mechanism 50 and the first and second hinge blades 21 and 22, and the connection configuration is accomplished by forming a rectangular tension guide hole 58a on one side of each of the first and second hinge blades 21 and 22, and forming a tension guide protrusion 58b on each of the first and second tension blades 55 and 56 of the tension mechanism 50 to be inserted and guided in the tension guide hole 58a.

Accordingly, the first and second tension blades 55 and 56 of the tension mechanism 50 rotate between the ‘unfolded position’ and the ‘folded position’ in connection with the first and second hinge blades 21 and 22.

As the slope protrusions 55a and 56a of the first and second tension blades 55 and 56 are insert-fitted to or separated from the slope protrusions 53a and 54a of the tension operating members 53 and 54 according to rotation of the first and second tension blades 55 and 56, and therefore, elastic force of the first and second springs 57a and 57b is increased or decreased, the tension mechanism 50 performs handling of rotation of the first and second bodies 11 and 12 with a small force at the ‘unfolded position’ or ‘folded position’, and performs a free stop function between the ‘unfolded position’ and the ‘folded position’.

The free stop function means that when the rotation is stopped by removing the rotational force while rotating the first and second bodies 11 and 12 to the ‘unfolded position’ or ‘folded position’, the first and second bodies 11 and 12 stay as they are at the positions where the rotation is stopped.

Although an embodiment of the tension mechanism 50 has been described above, any configuration that can easily handle rotation of the bodies 11 and 12 with a small force and perform the free stop function may be applied to the present invention in combination with the characteristic configuration including the sloping plate and lifting plate described below.

Referring to FIGS. 4 and 5 again, the hinge device 14 of the present invention includes first and second sloping plates 61 and 62 installed on the first hinge blade 21 and the second hinge blade 22, respectively.

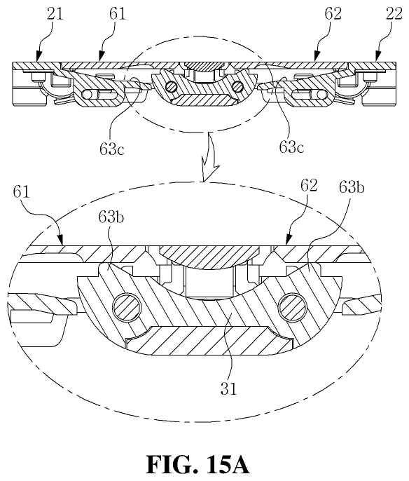

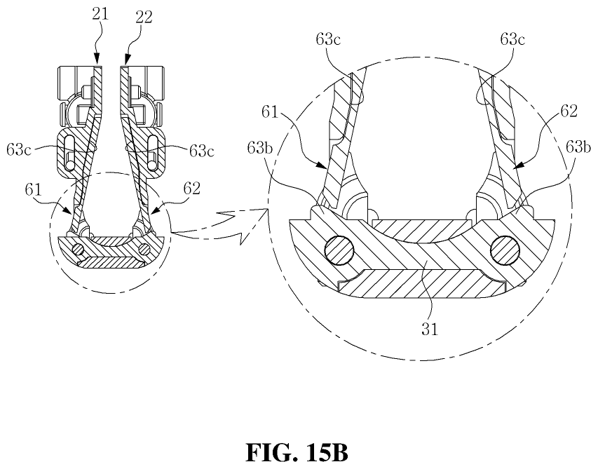

The first and second sloping plates 61 and 62 are installed to interwork by a first pressing means described below during the rotation movement of the first hinge blade 21 and the second hinge blade 22 so as to move between a horizontal position aligned with the horizontal line of the first and second bodies 11 and 12 at the ‘unfolded position’ (see FIG. 15a) and a sloping position arranged to be inclined from the horizontal line of the first body 11 and the second body 12 toward the outside so that a folding space is formed between the first hinge blade 21 and the second hinge blade 22 at the ‘folded position’.

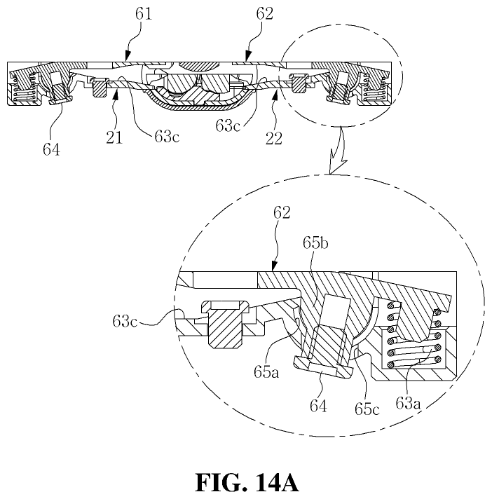

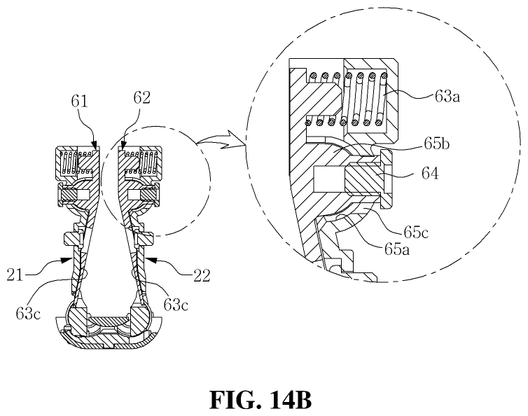

FIGS. 14a and 14b are views showing the installation configuration and the operation state of the first and second sloping plates 61 and 62, and FIG. 14a is a cross-sectional view taken along the line A-A in FIG. 4, showing an unfolded position, and FIG. 14b is a view showing a folded position.

As shown in the figure, the first and second sloping plates 61 and 62 are fixed to the first and second hinge blades 21 and 22 by means of screws 64. As semicircular rotation support grooves 65a are formed on the first and second hinge blades 21 and 22 at the portions fixed using the screws 64, and semicircular rotation support protrusions 65b are formed on the first and second sloping plates 61 and 62, the first and second sloping plates 61 and 62 may rotate as much as a predetermined angle between the horizontal position and the sloping position around the semicircular rotation support protrusions 65b.

At this point, assembly holes 65c of the first and second hinge blades 21 and 22 through which the screws 64 pass are formed to be slightly long in the rotation direction of the first and second sloping plates 61 and 62 to guide the first and second sloping plates 61 and 62 to rotate as much as a predetermined angle.

In addition, the first pressing means is configured of first elastic members 63a elastically installed between the first and second hinge blades 21 and 22 and the first and second sloping plates 61 and 62 to provide an elastic force so that the first and second sloping plates 61 and 62 are always at the sloping position, and first pressing protrusions 63b provided in the housing 31 to maintain the horizontal position by pressing one sides of the first and second sloping plates 61 and 62 at the ‘unfolded position’ (see FIGS. 8 and 15a).

In addition, sloping surfaces 63c are formed on the first and second hinge blades 21 and 22 to form a folding space at the ‘folded position’. The sloping surfaces 63c are formed to be inclined toward the outside as much as a predetermined angle from the horizontal line corresponding to the inner sides of the first body 21 and the second body 22, and configured to form a folding space always at a predetermined sloping position as the first and second sloping plates 61 and 62 are tightly attached to the sloping surfaces 63c by the elastic force of the first clastic members 63a at the sloping position.

Referring to FIGS. 4 and 5 again, the hinge device 14 of the present invention includes a lifting plate 70 disposed between the first and second sloping plates 61 and 62. As shown in FIG. 5, the lifting plate 70 may be installed as one piece by connecting the symmetrical structures on both sides, or may be installed in two pieces by separating the symmetrical structures from each other.

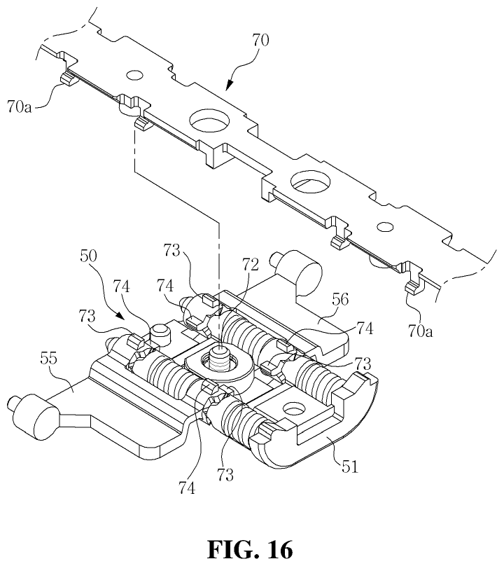

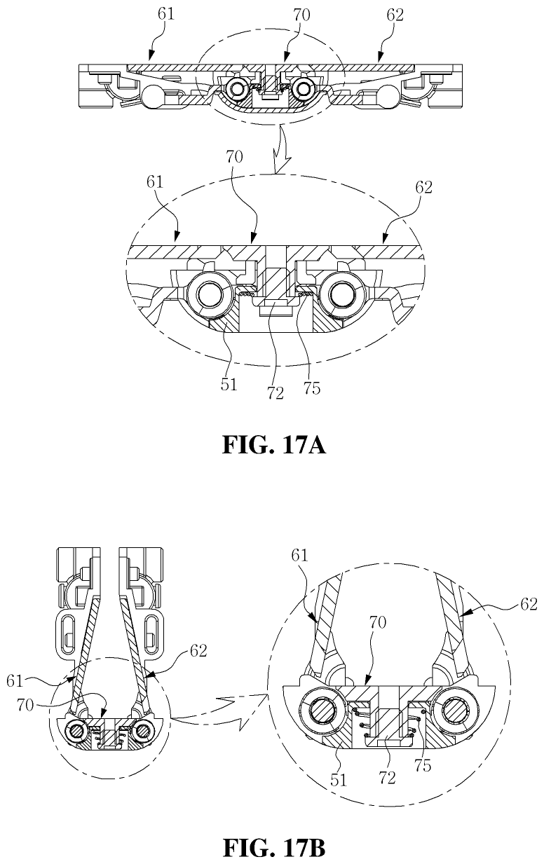

As shown in FIGS. 16, 17a, and 17b, the lifting plate 70 is positioned on the tension fixed member 51 of the tension mechanism 50, and is installed as a screw 72 passes through from the bottom of the tension fixed member 51 and is fastened to the lifting plate 70.

The lifting plate 70 is configured to interwork by a second pressing means described below during the rotation movement of the first and second tension blades 55 and 56 so as to move between an ascending position connecting the gap between the first sloping plates 61 and 62 and the second sloping plates 61 and 62 on the same horizontal line (see FIG. 17a) at the ‘unfolded position’ and a descending position that forms a folding space between the first hinge blade 21 and the second hinge blade 22 at the ‘folded position’ (see FIG. 17b).

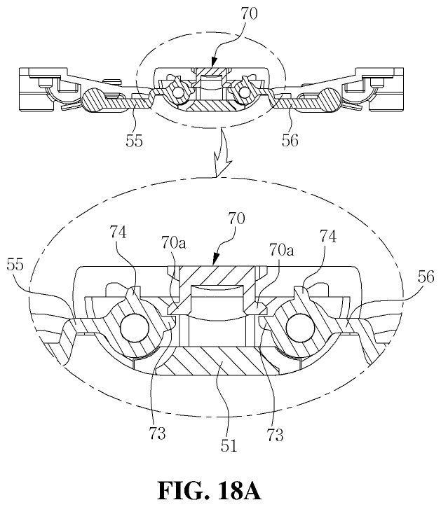

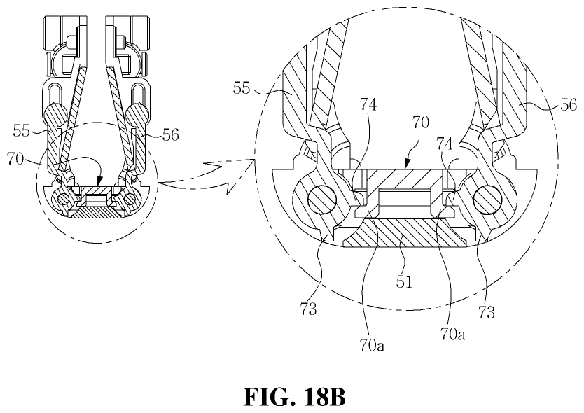

The second pressing means is configured of second elastic members 75 elastically installed between the tension fixed member 51 and the screw 72 to provide an elastic force so that the lifting plate 70 is always at the descending position, and second and third pressing protrusions 73 and 74 formed on the first and second tension blades 55 and 56 of the tension mechanism 50 as shown in FIGS. 18a and 18b.

The second elastic members 75 are compressed when the lifting plate 70 is at the ascending position as shown in FIG. 17a and are extended when the lifting plate 70 is at the descending position as shown in FIG. 17b to provide elastic force in the direction in which the lifting plate 70 always moves to the descending position.

The second and third pressing protrusions 73 and 74 are arranged in the circumferential direction around the hinge axis line as shown in FIGS. 18a and 18b, and it is configured so that the second pressing protrusions 73 maintain the lifting plate 70 at the ascending position by pressing one side 70a of the lifting plate 70 when the first and second tension blades 55 and 56 rotate to the unfolded position as shown in FIG. 18a, and the third pressing protrusions 74 maintain the lifting plate 70 at the descending position by pressing one side of the lifting plate 70 when the first and second tension blades 55 and 56 rotate to the folded position as shown in FIG. 18b.

The operation of the hinge device according to the present invention configured as described above will be described below.

When the first and second bodies 11 and 12 are moved between the ‘unfolded position’ as shown in FIG. 2a and the ‘folded position’ as shown in FIG. 2b, as the semicircular grooves 21a and 22a of the first and second hinge blades 21 and 22 respectively fixed to the first and second bodies 11 and 12 are guided to the semicircular protrusions 31a and 31b of the housing 31 to rotationally support as shown in FIGS. 7a and 7b, the operation of moving the first and second bodies 11 and 12 from the ‘unfolded position’ to the ‘folded position’ is performed smoothly.

In addition, when only any one of the first body 11 and the second body 12 rotates, the other one performs a relative motion by the interworking means to rotate together.

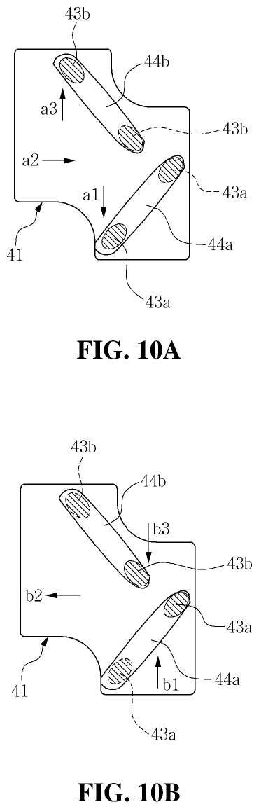

That is, when the slope guide protrusion 43a of the first hinge blade 21 moves in the direction of arrow ‘a1’ in the state of an imaginary line as shown in FIG. 10a by rotating only the first hinge blade 21 to the ‘folded position’, the slide member 41 moves in the direction of arrow ‘a2’ by the first slope guide groove 44a, and the slope guide protrusion 43b of the second hinge blade 22 is guided by the second slope guide groove 44b and moves in the direction of arrow ‘a3’ in the state of an imaginary line, and therefore, the second hinge blade 22 also interworks with the first hinge blade 21 toward the ‘folded position’.

On the contrary, although the slope guide protrusion 43b of the second hinge blade 22 is moved in the direction of arrow ‘a3’, the slope guide protrusion 43a of the first hinge blade 21 moves in the direction of arrow ‘a1’ by the first and second slope guide grooves 44a and 44b of the slide member 41, and therefore, the first hinge blades 21 may interwork.

In the same manner, when the slope guide protrusion 43a of the first hinge blade 21 moves in the direction of arrow ‘b1’ in the state of an imaginary line as shown in FIG. 10b by rotating only the first hinge blade 21 to the ‘unfolded position’, the slide member 41 moves in the direction of arrow ‘b2’ by the first slope guide groove 44a, and the slope guide protrusion 43b of the second hinge blade 22 is guided by the second slope guide groove 44b and moves in the direction of arrow ‘b3’ in the state of an imaginary line, and therefore, the second hinge blade 22 also interworks with the first hinge blade 21 toward the ‘unfolded position’.

On the contrary, although the slope guide protrusion 43b of the second hinge blade 22 is moved in the direction of arrow ‘b3’, the slope guide protrusion 43a of the first hinge blade 21 moves in the direction of arrow ‘b1’ by the first and second slope guide grooves 44a and 44b of the slide member 41, and therefore, the first hinge blades 21 may interwork.

In FIGS. 10a and 10b, the first and second slope guide protrusions 43a and 43b appear to move diagonally while being engaged with the first and second slope guide grooves 44a and 44b formed on the slide member 41, and as the interworking slide member 41 performs a linear movement in the direction of hinge axis line, the first and second hinge blades 21 and 22, on which the first and second slope guide protrusions 43a and 43b are formed, linearly move up and down (a1 and b1 directions and a3 and b3 directions) on the plan view as a result. However, as the first and second slope guide grooves 44a and 44b are formed as curved surfaces along the length, and the portions where the first and second slope guide protrusions 43a and 43b are formed are also formed as curved surfaces in the rotation direction, the first and second hinge blades 21 and 22, on which the first and second slope guide grooves 44a and 44b are formed, perform rotation movement to the ‘folded position’ or ‘unfolded position’ as a result.

In addition, the hinge device 14 of the present invention performs a free stop function by the tension mechanism 50 when the rotation positions of the first and second bodies 11 and 12 are between the ‘unfolded position’ and the ‘folded position’.

In the tension mechanism 50, as the tension guide protrusions 58b of the first and second tension blades 55 and 56 are guided to the tension guide holes 58a of the first and second hinge blades 21 and 22 as shown in FIG. 11, when the first and second hinge blades 21 and 22 rotate, the first and second tension blades 55 and 56 interwork and rotate together.

Therefore, as the tension operating members 53 and 54 move along the first and second guide shafts 52a and 52b and compress the first and second springs 57a and 57b, the clastic force of the first and second springs 57a and 57b that press the tension operating members 53 and 54 toward the first and second tension blades 55 and 56 is increased, and a free stop function of maintaining the first and second bodies 11 and 12 as they are at a stopped position may be performed using the increased elastic force when the first and second bodies 11 and 12 are stopped during rotation.

In addition, as the first and second sloping plates 61 and 62 and the lifting plate 70 interwork when the first and second hinge blades 21 and 22 rotate between the ‘unfolded position’ and the ‘folded position’, the hinge device 14 of the present invention may maintain the folding unit P of the flexible display panel 13 in a horizontal state at the ‘unfolded position’ of the first and second bodies 11 and 12 as shown in FIG. 2a, and in addition, as shown in FIG. 2b, a folding space that can accommodate a predetermined radius of curvature R formed in the folding unit P of the display panel may be formed at the ‘folded position’ of the first and second bodies 11 and 12.

That is, when the first and second hinge blades 21 and 22 are at the ‘folded position’ as shown in FIG. 14b, the first and second sloping plates 61 and 62 are at a sloping position tightly attached to the sloping surfaces 63c of the first and second hinge blades 21 and 22 by the elastic force of the first elastic members 63a, and one-end portions of the first and second sloping plates 61 and 62 are positioned on the first pressing protrusions 63b of the housing 31 as shown in FIG. 15b.

In addition, the lifting plate 70 is at the descending position by the elastic force of the second elastic members 75 as shown in FIG. 17b, and the third pressing protrusions 74 provided on the first and second tension blades 55 and 56 of the tension mechanism 50 press and maintain one sides 70a of the lifting plate 70 as shown in FIG. 18b.

When the first and second bodies 11 and 12 rotate from this ‘folded position’ to the ‘unfolded position’, the first and second hinge blades 21 and 22 respectively fixed to the first and second bodies 11 and 12 as shown in FIG. 15a rotate together. At this point, as the end portions of the first and second sloping plates 61 and 62 are in contact with the first pressing protrusions 63b of the housing 31, the first and second sloping plates 61 and 62 rotate around the rotation support protrusions 65b as shown in FIG. 14a and move to a horizontal position spaced apart from the sloping surfaces 63c, and the first elastic members 63a are in a compressed state.

In addition, the third pressing protrusions 74 are spaced apart from the lifting plate 70 by rotation of the first and second tension blades 55 and 56 as shown in FIG. 18a, and as the second pressing protrusions 73 press one sides 70a of the lifting plate 70 and the lifting plate 70 move from the descending position to the ascending position, the second elastic members 75 are in a compressed state as shown in FIG. 17a.

When the first and second sloping plates 61 and 62 move to the horizontal position in this way and the lifting plate 70 moves to the ascending position, as the first and second sloping plates 61 and 62 are aligned with the horizontal line of the first and second bodies 11 and 12 at the horizontal position as shown in FIG. 17a, the folding unit P of the flexible display panel 13 is maintained in the horizontal state (see FIG. 2a), and as the lifting plate 70 connects the gap between the first and second sloping plates 61 and 62 on the same horizontal line at the ascending position, the horizontal state of the folding unit P of the flexible display panel 13 may be successively maintained without fail.

Subsequently, when the first and second bodies 11 and 12 rotate from the ‘unfolded position’ as described above to the ‘folded position’, the first and second hinge blades 21 and 22 respectively fixed to the first and second bodies 11 and 12 rotate together as shown in FIG. 14b. At this point, since the first and second sloping plates 61 and 62 are provided with elastic force for rotating to the sloping position by the compressed first elastic members 63a, the first and second sloping plates 61 and 62 rotate around the rotation support protrusions 65b and move to the sloping position tightly attached to the sloping surfaces 63c.

In addition, in the lifting plate 70, the second pressing protrusions 73 are spaced apart from the lifting plate 70 as shown in FIG. 18b, and the third pressing protrusions 73 press one sides 70a of the lifting plate 70 to move from the ascending position to the descending position, and at the same time, the elastic force of the second elastic members 75 compressed as shown in FIG. 17b assists descending movement of the lifting plate 70.

As described above, when the first and second sloping plates 61 and 62 move to the sloping position and the lifting plate 70 moves to the descending position, a wide space is secured between the first and second hinge blades 21 and 22, and thus a folding space that can accommodate a predetermined radius of curvature R formed in the folding unit P of the flexible display panel 13 can be formed. Accordingly, the hinge device of the present invention may allow the display panel attached to the first and second bodies 11 and 12 to be folded in parallel at the ‘folded position’ other than the folding unit, while forming a predetermined radius of curvature in the folding unit P (see ‘dumbbell shape’ in FIG. 2b).

As described above, the hinge device of the present invention may form the outer side and the inner side to be parallel while the inner sides of the first body 11 and the second body 12 are in contact with each other at the ‘folded position’, while maintaining the folding unit P of the flexible display panel 13 in a horizontal state at the ‘unfolded position’ of the first and second bodies 11 and 12, and forming a folding space that can accommodate a predetermined radius of curvature R formed in the folding unit P of the flexible display panel 13 at the ‘folded position’, and therefore, the outer shape of the mobile device can be simplified, and contamination of the flexible display panel caused by foreign substances while carrying the mobile device can be prevented by eliminating the gap between the first and second bodies 11 and 12.

In the hinge device of the present invention described above, as the display panel is folded in a dumbbell shape by maintaining a horizontal state at the ‘unfolded position’ and forming a folding space that accommodates a predetermined radius of curvature R at the ‘folded position’, the configuration including the sloping plate or the lifting plate, which allows the inner sides of the bodies to contact with each other at the ‘folded position’ and forms the outer side and the inner side to be parallel, may be applied in combination with various rotation-supporting structures, interworking means, or tension mechanisms, in addition to the rotation-supporting structure, interworking means, or tension mechanism of the embodiment described above that can be coupled thereto.

The hinge device of the present invention may be used in various devices to which a foldable hinge structure is applied, such as a notebook computer or the like, in addition to mobile devices such as cellular phones.

As described above, optimal embodiments are disclosed in the drawings and specifications. Although specific terms are used herein, they are used only for the purpose of describing the present invention and are not used to limit the meaning or scope of the present invention described in the claims. Therefore, those skilled in the art will understand that various modifications and other equivalent embodiments are possible therefrom. Accordingly, the truc technical protection scope of the present invention should be determined by the technical spirit of the attached patent claims.

1. A hinge device comprising:
a housing positioned between one-end portions of a first body and a second body performing a relative motion with each other;
a first hinge blade and a second hinge blade fixed to the first body and the second body and rotationally supported on the housing to perform rotation movement as much as a predetermined angle between an ‘unfolded position’ at which the first body and the second body are placed on the same horizontal line and a ‘folded position’ at which the first body and the second body are facing and in contact with each other; and
a first sloping plate and a second sloping plate installed on the first hinge blade and the second hinge blade, respectively, to interwork by pressure during the rotation movement of the first hinge blade and the second hinge blade so as to move between a horizontal position aligned with a horizontal line of the first body and the second body at the ‘unfolded position’ and a sloping position arranged to be inclined from the horizontal line of the first body and the second body so that a folding space is formed between the first hinge blade and the second hinge blade at the ‘folded position’.

2. The device according to claim 1, wherein the first sloping plate and the second sloping plate interwork by a first pressing means, wherein the first pressing means is configured of first elastic members for providing an elastic force so that the first sloping plate and the second sloping plate are always at the sloping position, and first pressing protrusions for maintaining the first hinge blade and the second hinge blade at the horizontal position by pressing the first sloping plate and the second sloping plate when the first hinge blade and the second hinge blade rotate to the ‘unfolded position’.

3. The device according to claim 1, wherein as rotation support grooves are formed on the first hinge blade and the second hinge blade, and rotation support protrusions are formed on the first sloping plate and the second sloping plate, the first and second sloping plates may rotate as much as a predetermined angle between the horizontal position and the sloping position around the rotation support protrusions.

4. The device according to claim 3, wherein assembly holes of the first hinge blade and the second hinge blade combined with the first sloping plate and the second sloping plate are formed to be slightly long in a rotation direction of the first sloping plate and the second sloping plate to guide the first sloping plate and the second sloping plate to rotate as much as a predetermined angle.

5. The device according to claim 1, wherein as sloping surfaces that can be tightly attached to the first sloping plate and the second sloping plate at the sloping positions of the first sloping plate and the second sloping plate are formed on the first hinge blade and the second hinge blade, a folding space is formed always at a predetermined sloping position by a pressing member.

6. The device according to claim 1, further comprising a lifting plate installed in the housing to be positioned in a folding space between the first sloping plate and the second sloping plate, to interwork by pressure during the rotation movement of the first hinge blade and the second hinge blade, so as to move between an ascending position spaced apart from the housing to connect a gap between the first sloping plates and the second sloping plates on the same horizontal line at the unfolded position and a descending position close to the housing to form a folding space between the first hinge blade and the second hinge blade at the folded position.

7. The device according to claim 6, wherein the lifting plate interworks by a second pressing means, wherein the second pressing means is configured of second elastic members for providing an elastic force so that the lifting plate is always at the descending position, and second and third pressing protrusions for pressing the lifting plate to move to the ascending position and the descending position.

8. The device according to claim 1, wherein at the ‘folded position’, the display panel attached to the first and second bodies is allowed to be folded in parallel, in portions other than the folding unit, while forming a predetermined radius of curvature in the folding unit.
